(19) United States
(12) Patent Application Publication
(10) Pub. No.: US 2025/0204120 A1
(43) Pub. Date: Jun. 19, 2025

(54) WIRING BOARD, PLANAR LIGHT-EMITTING DEVICE, AND PRODUCTION METHODS THEREFOR

(71) Applicant: NICHIA CORPORATION, Anan-shi (JP)

(72) Inventors: Masaaki KATSUMATA, Anan-shi (JP); Takashi KAWAMATA, Tokushima-shi (JP); Eiko MINATO, Anan-shi (JP)

(73) Assignee: NICHIA CORPORATION, Anan-shi (JP)

(21) Appl. No.: 18/697,003

(22) PCT Filed: Sep. 21, 2022
(86) PCT No.: PCT/JP2022/035103

§ 371 Date: Dec. 23, 2024

(30) Foreign Application Priority Data
Sep. 30, 2021 (JP) 2021-162369

(51) Int. Cl. H10H 29/01; F21K 9/90; F21V 23/00; F21Y 105/16; H01L 25/075; H10H 29/24; H10H 29/85

(52) U.S. Cl. CPC H10H 29/0364; H01L 25/0753; H10H 29/24; H10H 29/857; F21K 9/90; F21V 23/002; F21Y 2105/16

(57) ABSTRACT

A method of manufacturing a wiring board includes: providing a substrate including an insulating resin and a metal member provided with an anti-rust layer on a surface facing a second surface of the insulating resin; forming a plurality of first holes passing through the metal member by etching; forming a second hole passing through the insulating resin and communicating with at least one of the first holes from a first surface side of the insulating resin; and filling an electroconductive paste to connect the second hole with any of the plurality of first holes and disposing the electroconductive paste on the first surface of the insulating resin to form wiring continuous with the filled electroconductive paste, the anti-rust layer on the surface of the metal member being removed from an inner bottom surface of the second hole in the forming of the second hole.

### CROSS-REFERENCE TO RELATED APPLICATIONS

The present application is a national phase application of PCT Application No. PCT/JP2022/035103, filed on Sep. 21, 2022, and claims priority to JP Application No. 2021-162369, filed on Sep. 30, 2021, the entire contents of which are herein incorporated by reference.

### BACKGROUND

### 1. Technical Field

The present disclosure relates to a wiring board, a planar light-emitting device, and manufacturing methods thereof.

### 2. Description of Related Art

As interlayer wiring of a multilayer wiring board, vias in which an electroconductive paste has been filled are employed in some cases. For example, Japanese Patent Publication No. 2006-210514 describes a double-sided wiring board that is provided with wiring made of copper foil on both surfaces of the board and includes, as interlayer wiring, vias in which an electroconductive paste has been filled.

### SUMMARY

An embodiment according to the present disclosure provides a wiring board the production time and number of steps for which can be reduced, a planar light-emitting device, and manufacturing methods thereof.

A method of manufacturing a wiring board described herein includes: providing a substrate including an insulating resin having a first surface and a second surface opposite to the first surface and a metal member provided with an anti-rust layer on a surface facing the second surface of the insulating resin; forming a plurality of first holes passing through the metal member by etching in the metal member; forming a second hole passing through the insulating resin and communicating with at least one of the first holes from a first surface side of the insulating resin; and filling an electroconductive paste to connect the second hole with any of the plurality of first holes and disposing the electroconductive paste on the first surface of the insulating resin to form wiring continuous with the filled electroconductive paste, the anti-rust layer on the surface of the metal member being removed from an inner bottom surface of the second hole along with formation of the second hole in the forming a second hole.

A method of manufacturing a planar light-emitting device described herein includes: manufacturing the wiring board by the method of manufacturing a wiring board described above; disposing a light source including a light-emitting element on the metal member of the wiring board; disposing a light-reflective member to cover the metal member; and disposing a first light-guiding member to cover the light-reflective member.

A method of manufacturing a planar light-emitting device described herein includes: manufacturing the wiring board by the method of manufacturing a wiring board described above; a step of disposing a light-reflective member to cover the first surface of the insulating resin in the wiring board and the electroconductive paste; disposing a light source including a light-emitting element on the first surface side of the insulating resin; disposing a light-guiding member to cover the light source and the light-reflective member; and disposing a light adjusting member at a position on a surface of the light-guiding member, the position overlapping the light source in a plan view.

A wiring board described herein includes: a substrate including an insulating resin having a first surface and a second surface opposite to the first surface and a metal member provided with an anti-rust layer on a surface facing the second surface of the insulating resin; and an electroconductive paste disposed on the substrate, a plurality of first holes passing through the metal member, a second hole passing through the insulating resin and communicating with at least one of the first holes, the anti-rust layer on the surface of the metal member being absent from an inner bottom surface of the second hole, the electroconductive paste being filled to connect at least a portion of the second hole with any of the plurality of first holes and disposed on the first surface of the insulating resin to form wiring continuous with the filled electroconductive paste.

A planar light-emitting device described herein includes: the wiring board described above; a light source including a light-emitting element, the light source disposed on the metal member of the wiring board; a light-reflective member covering the metal member; and a first light-guiding member covering the light-reflective member.

A planar light-emitting device described herein includes: the wiring board described above; a light-reflective member covering the first surface of the insulating resin in the wiring board and the electroconductive paste; a light source including a light-emitting element, the light source disposed on the first surface side of the insulating resin; a light-guiding member covering the light source and the light-reflective member; and a light adjusting member disposed at a position on a surface of the light-guiding member, the position overlapping the light source in a plan view.

With the embodiments in the present disclosure, a wiring board with which it is possible to suppress an increase in the types of members in a double-sided board and to decrease the production time and the number of steps, a planar light-emitting device, and manufacturing methods thereof can be provided.

### BRIEF DESCRIPTION OF DRAWINGS

A more complete appreciation of embodiments of the invention and many of the attendant advantages thereof will be readily obtained by reference to the following detailed description when considered in connection with the accompanying drawings.

FIG. 1A is a schematic perspective view from a second surface side showing an example of a portion of a wiring board according to an embodiment.

FIG. 1B is a schematic perspective view from a first surface side showing an example of a portion of the wiring board according to the embodiment.

FIG. 1C is a schematic plan view from the second surface side showing an example of a portion of the wiring board according to the embodiment.

FIG. 1D is a schematic plan view from the first surface side showing an example of a portion of the wiring board according to the embodiment.

FIG. 2A is a schematic plan view from the first surface side showing an example of a via connection portion according to the embodiment.

FIG. 2B is a schematic plan view in which an electroconductive paste has been removed from FIG. 2A.

FIG. 2C is a schematic cross-sectional view showing an example of a cross section along the line IIC-IIC of FIG. 2A.

FIG. 3 is a flowchart illustrating an example of a method of manufacturing the wiring board according to the embodiment.

FIG. 4A is a schematic cross-sectional view of an example of a substrate provided in the method of manufacturing the wiring board according to the embodiment.

FIG. 4B is a schematic cross-sectional view showing an example of a state in which first holes have been formed in the method of manufacturing the wiring board according to the embodiment.

FIG. 4C is a schematic cross-sectional view showing an example of a state in which a second hole has been formed in the method of manufacturing the wiring board according to the embodiment.

FIG. 4D is a schematic cross-sectional view showing an example of a state in which the electroconductive paste is injected into the second hole in the method of manufacturing the wiring board according to the embodiment.

FIG. 4E is a schematic cross-sectional view showing an example of a state in which the electroconductive paste has been disposed in the method of manufacturing the wiring board according to the embodiment.

FIG. 5A is a schematic plan view of an example of a planar light-emitting device according to first and second embodiments.

FIG. 5B is a schematic enlarged plan view of an example of a portion of FIG. 5A.

FIG. 5C is a schematic plan view of an example of a portion of the wiring board in the planar light-emitting device according to a first embodiment.

FIG. 6 is a schematic cross-sectional view showing an example of a cross-section of the planar light-emitting device according to the first embodiment along the line VI-VI of FIG. 5B.

FIG. 7 is a flowchart illustrating an example of a method of manufacturing the planar light-emitting device according to the first embodiment.

FIG. 8A is a schematic cross-sectional view of an example of the wiring board manufactured by the method of manufacturing the wiring board according to the embodiment in the method of manufacturing the planar light-emitting device according to the first embodiment.

FIG. 8B is a schematic cross-sectional view showing an example of a state in which light sources have been disposed in the method of manufacturing the planar light-emitting device according to the first embodiment.

FIG. 8C is a schematic cross-sectional view showing an example of a state in which a light-reflective member has been disposed in the method of manufacturing the planar light-emitting device according to the first embodiment.

FIG. 8D is a schematic cross-sectional view showing an example of a state in which a first light-guiding member has been disposed in the method of manufacturing the planar light-emitting device according to the first embodiment.

FIG. 8E is a schematic cross-sectional view showing an example of a state in which second light-guiding members have been disposed in the method of manufacturing the planar light-emitting device according to the first embodiment.

FIG. 8F is a schematic cross-sectional view showing an example of a state in which light adjusting members have been disposed in the method of manufacturing the planar light-emitting device according to the first embodiment.

FIG. 9A is a schematic cross-sectional view of an example of a planar light-emitting device according to a first modified example of the first light-guiding member.

FIG. 9B is a schematic cross-sectional view of an example of a planar light-emitting device according to a second modified example of the first light-guiding member.

FIG. 9C is a schematic cross-sectional view of an example of a planar light-emitting device according to a third modified example of the first light-guiding member.

FIG. 10 is a schematic cross-sectional view showing an example of a cross section of the planar light-emitting device according to the second embodiment along the line X-X of FIG. 5B.

FIG. 11 is a flowchart illustrating an example of a method of manufacturing the planar light-emitting device according to the second embodiment.

FIG. 12A is a schematic cross-sectional view of an example of the wiring board manufactured by the method of manufacturing the wiring board according to the embodiment in the method of manufacturing the planar light-emitting device according to the second embodiment.

FIG. 12B is a schematic cross-sectional view showing an example of a state in which a light-reflective member has been disposed in the method of manufacturing the planar light-emitting device according to the second embodiment.

FIG. 12C is a schematic cross-sectional view showing an example of a state in which through holes have been formed in the method of manufacturing the planar light-emitting device according to the second embodiment.

FIG. 12D is a schematic cross-sectional view showing an example of a state in which the light sources have been disposed in the method of manufacturing the planar light-emitting device according to the second embodiment.

FIG. 12E is a schematic cross-sectional view showing an example of a state in which connecting members have been disposed in the method of manufacturing the planar light-emitting device according to the second embodiment.

FIG. 12F is a schematic cross-sectional view showing an example of a state in which the first light-guiding member has been disposed in the method of manufacturing the planar light-emitting device according to the second embodiment.

FIG. 12G is a schematic cross-sectional view showing an example of a state in which the second light-guiding members have been disposed in the method of manufacturing the planar light-emitting device according to the second embodiment.

FIG. 12H is a schematic cross-sectional view showing an example of a state in which the light adjusting members have been disposed in the method of manufacturing the planar light-emitting device according to the second embodiment.

### DETAILED DESCRIPTION

Certain embodiments according to the present disclosure will be described below referring to the accompanying drawings. The embodiments described below are intended to give a concrete form to the technical idea according to the present disclosure. The present invention is not limited to the embodiments below unless specifically stated otherwise. Description in one embodiment is applicable to other embodiments and modified examples. The drawings schematically illustrate certain embodiments, and the scales, the distances, the positional relationships, and the like of members may be exaggerated, or illustration of portions of members may be omitted to clarify the descriptions. A direction in each drawing is not intended to indicate absolute positions but represents relative positions of components. The same term or reference numeral generally represents the same member or a member made of the same material, and its detailed description will be omitted as appropriate. The term “cover” as used in the embodiments includes not only being in direct contact but rather also includes indirect covering, such as covering via another member disposed therebetween.

### Wiring Board

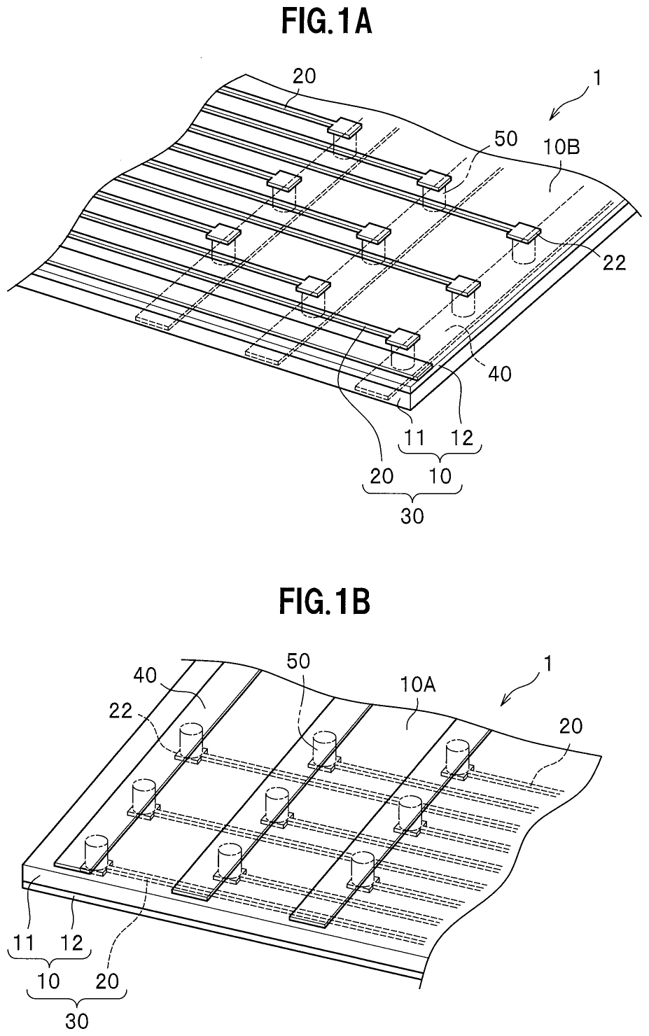

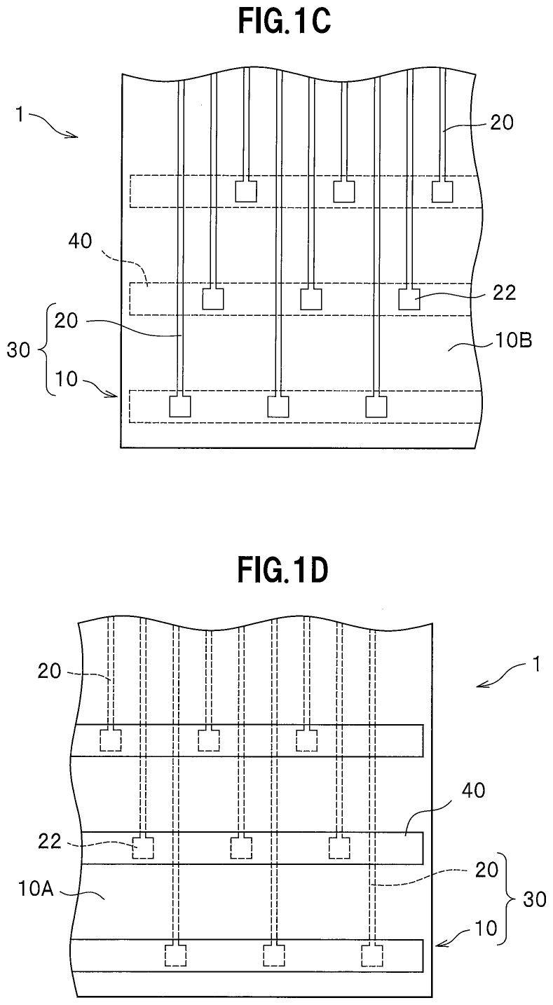

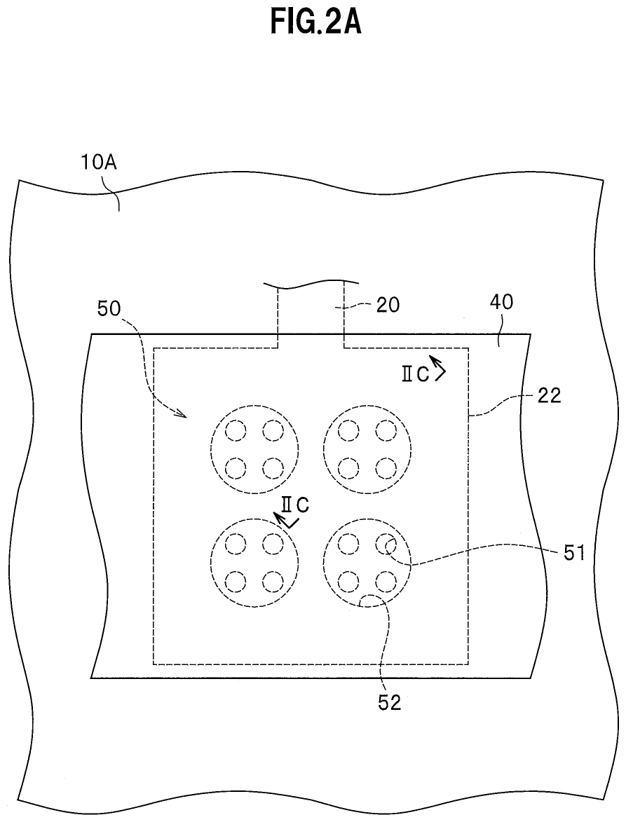

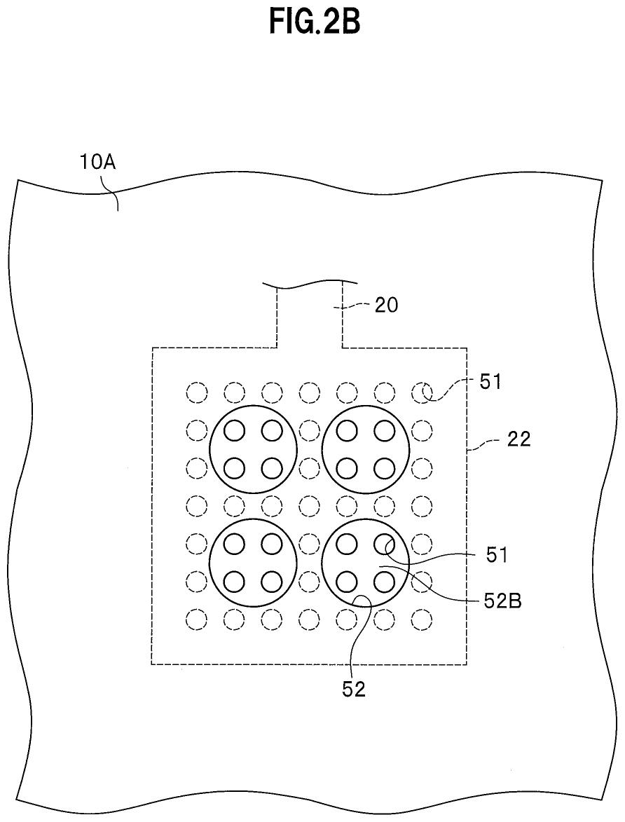

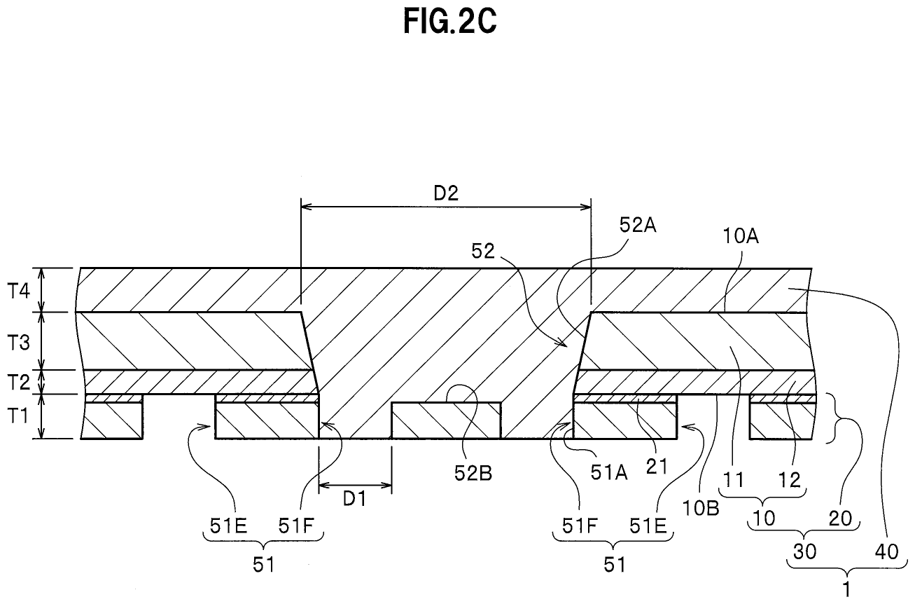

A wiring board 1 according to an embodiment will be described referring to FIG. 1A to FIG. 2C.

FIG. 1A is a schematic perspective view from a second surface side showing an example of a portion of the wiring board according to the embodiment. FIG. 1B is a schematic perspective view from a first surface side showing an example of a portion of the wiring board according to the embodiment. FIG. 1C is a schematic plan view from the second surface side showing an example of a portion of the wiring board according to the embodiment. FIG. 1D is a schematic plan view from the first surface side showing an example of a portion of the wiring board according to the embodiment. FIG. 2A is a schematic plan view from the first surface side showing an example of a via connection portion according to the embodiment. FIG. 2B is a schematic plan view in which an electroconductive paste has been removed from FIG. 2A. FIG. 2C is a schematic cross-sectional view showing an example of a cross section along the line IIC-IIC of FIG. 2A.

The wiring board 1 can be provided with different electrical wiring patterns on both surfaces. The wiring patterns on both surfaces are connected by a via connection portion 50. One surface of the wiring board 1 is provided with wiring of a metal member 20 described below, and the opposite surface is provided with wiring formed of an electroconductive paste 40 described below. The via connection portion 50 has first holes 51 and second holes 52 described below and connects the wiring on both surfaces through the electroconductive paste 40. An enlarged view of an example of the via connection portion 50 is shown in FIG. 2A.

The wiring board 1 includes: a substrate 30 including an insulating resin 10 having a first surface 10A and a second surface 10B opposite to the first surface 10A and the metal member 20 provided with an anti-rust layer 21 on a surface facing the second surface 10B of the insulating resin 10; and the electroconductive paste 40 disposed in the substrate 30, a plurality of first holes 51 passing through the metal member 20, a second hole 52 passing through the insulating resin 10 and communicating with at least one of the first holes 51, the anti-rust layer 21 on the surface of the metal member 20 being absent from an inner bottom surface 52B of the second hole 52, the electroconductive paste 40 being filled to connect the second hole 52 with any of the plurality of first holes 51 and disposed on the first surface 10A of the insulating resin 10 to form wiring continuous with the filled electroconductive paste 40. Description of components of the wiring board 1 will be given below.

### Substrate

The substrate 30 is a plate-shaped or sheet-shaped member serving as the base of the wiring board 1. For example, the substrate 30 has a rectangular shape in a plan view. The shape of the substrate 30 in a plan view is not particularly limited. The substrate 30 includes the insulating resin 10 and the metal member 20 serving as wiring facing the second surface 10B of the insulating resin 10. The first surface 10A of the insulating resin 10 is provided with the electroconductive paste 40 serving as wiring. The wiring of the metal member 20 and the wiring of the electroconductive paste 40 are connected by the via connection portion 50 (through holes and the electroconductive paste) serving as wiring formed through the insulating resin 10.

### Insulating Resin

The insulating resin 10 is a plate-shaped or sheet-shaped insulating member serving as the foundation on which a wiring pattern is formed. The insulating resin 10 has the first surface 10A and the second surface 10B opposite to the first surface 10A and has the second hole 52 that is a through hole passing from the first surface 10A to the second surface 10B. In this example, the insulating resin 10 is made of two layers of a polyimide layer 11 and a resin layer 12. The first surface 10A is located on the polyimide layer 11 side, and the second surface 10B is located on the resin layer 12 side. A thickness T3 of the polyimide layer 11 is, for example, 12 μm or more and 75 μm or less, and a thickness T2 of the resin layer 12 is, for example, 5 μm or more and 20 μm or less. The material, structure, and thickness of the insulating resin 10 are not particularly limited.

### Metal Member

The metal member 20 is an electroconductive member constituting the wiring having a predetermined wiring pattern and a connection pad portion 22. The metal member 20 has a plurality of first holes 51, which are through holes, in a portion serving as the connection pad portion 22. For example, the material of the metal member 20 can be a single-element metal such as Ag, Al, Ni, Au, Cu, Ti, Pt, and W or an alloy containing any of these metals. In this example, copper foil is used as an example of the metal member 20. For example, a thickness T1 of the copper foil is 12 μm or more and 35 μm or less. The wiring having the wiring pattern and the connection pad portion 22 of the metal member 20 can be formed by etching.

A surface of the metal member 20 is rustproofed. In particular, the anti-rust layer 21 is formed on the surface facing the insulating resin 10. For example, the anti-rust layer 21 is made of a coarsened layer formed by coarsening treatment by forming asperities on the surface, a plating layer of Zn, Ni, or Cr, an organic film layer, or the like and constitutes the surface of the copper foil of the metal member 20. The anti-rust layer 21 suppresses oxidation of the metal member 20 such as copper foil and enhances adhesion to the insulating resin 10. The electrical resistance of the anti-rust layer 21 is larger than the electrical resistance of the copper foil. Accordingly, in the case in which an electrical contact is to be provided on the surface of the copper foil facing the insulating resin 10, the anti-rust layer 21 is preferably removed to reduce the electrical resistance at the electrical contact. For example, the anti-rust layer 21 can be removed by a method such as evaporation by applying laser light, removal by a chemical reaction using a reducing agent, and mechanical grinding. For example, the thickness of the anti-rust layer 21 is 0.1 μm or more and 7 μm or less. The area in which the anti-rust layer 21 has been removed relative to the inner bottom surface 52B of the second hole 52 is only required to be 20% or more, preferably 40% or more, more preferably 55% or more, still more preferably 70% or more. The area in which the anti-rust layer 21 has been removed relative to the inner bottom surface 52B of the second hole 52 is preferably 80% or less. The area in which the anti-rust layer 21 has been removed relative to the inner bottom surface 52B of the second hole 52 can be 100%. The electrical resistance between the electroconductive paste 40 and the metal member 20 can thus be reduced. The region in which the anti-rust layer 21 has been removed may not be located at only one position in the second hole 52 but may be located at a plurality of positions. Asperities may be formed on the surface of the metal member 20 in a portion in which the anti-rust layer 21 has been removed. For example, when the anti-rust layer 21 is removed using a laser or the like, fine asperities are formed on the surface of the metal member 20. The fine asperities can make the bonding between the electroconductive paste 40 and the metal member 20 firm. A surface roughness (Ra) of the metal member 20 in a portion in which the anti-rust layer 21 has been removed is preferably 0.1 μm to 3.0 μm, more preferably 0.2 μm to 1.5 μm.

The metal member 20 includes the connection pad portion 22 facing at least one second hole 52 in a plan view, and the first holes 51 are formed in the connection pad portion 22. In this example, the connection pad portion 22 has a rectangular shape and is located at the tip of the wiring having the wiring pattern of the metal member 20.

### Electroconductive Paste

The electroconductive paste 40 is a member that constitutes the wiring disposed on the first surface 10A and connects the wiring disposed on the first surface 10A and the metal member 20 facing the second surface 10B. The electroconductive paste 40 is disposed on the first surface 10A as wiring in a direction orthogonal to the direction of the wiring having the wiring pattern of the metal member 20 and filled into the first holes 51 and the second hole 52 at a position where the first holes 51 of the connection pad portion 22 face the region of the insulating resin 10 in which the second hole 52 is formed in a plan view.

The volume resistivity of the copper foil is, for example, 1.7 μΩ·cm, and the volume resistivity of the electroconductive paste 40 is, for example, 10 μΩ·cm or more and 100 μΩ·cm or less. In order to reduce the wiring resistance of the electroconductive paste 40, the cross-sectional area of the wiring can be increased. A wiring thickness T4 of the electroconductive paste 40 as the wiring disposed on the first surface 10A is, for example, 10 μm or more and 30 μm or less to make the wiring board 1 as thin as possible. The wiring width of the electroconductive paste 40 is preferably 0.5 mm or more and 2 mm or less.

Examples of a material of the electroconductive paste 40 include a mixture of a single-element material such as gold, silver, copper, platinum, and aluminum, an alloy thereof, or a mixed powder thereof and a resin binder. As the resin binder, for example, a thermosetting resin such as an epoxy resin and a silicone resin can be used. Further, the electroconductive paste 40 preferably contains a reducing agent such as an organic acid. The electrical resistance of the connection to the metal member 20 can thus be reduced. The electroconductive paste can be tin-silver-copper solder, tin-copper solder, tin-bismuth solder, or melting-point-shift solder containing a small amount of solder added and containing copper, silver, or the like. By using these materials, stability of the connection can be secured.

### First Hole and Second Hole

In a plan view, the second hole 52 provided in the insulating resin 10 is provided in the region facing the first holes 51 provided in the connection pad portion 22. In this example, as an example, four second holes 52 are provided in the region facing the first holes 51 provided in the connection pad portion 22.

As shown in FIG. 2C, the first holes 51 are provided in the connection pad portion 22 at positions facing the second holes 52 and around the positions facing the second holes 52. The electroconductive paste 40 is filled into the first holes 51 at positions facing the second holes 52 and is not filled into the first holes 51 around the positions facing the second holes 52.

In this example, four first holes 51 are provided in each region having the size of a single second hole 52 to face the second hole 52. In an example, regarding a single connection pad portion 22, 49 first holes 51 are provided in an array of 7 rows and 7 columns of first holes 51 in the region facing the four second holes 52.

In the wiring board 1 having the configuration as described above, the second hole 52 communicating with at least one first hole 51 in the metal member 20 is formed through the insulating resin 10, and the electroconductive paste 40 is filled to connect any of a plurality of first holes 51 and at least a portion of the second hole 52. In the wiring board 1, it is therefore possible to secure the electrical connection between the electroconductive paste 40 in the second hole 52 and the metal member 20.

In the wiring board 1, the anti-rust layer 21 on the surface of the metal member 20 is removed from the inner bottom surface 52B of the second hole 52, so that the electrical resistance of the connection between the electroconductive paste 40 and the metal member 20 can be reduced.

By providing many first holes 51, even in the case in which the insulating resin 10 expands and contracts in the processing, connection can be reliably established.

In the wiring board 1, the electroconductive paste 40 filled to connect any of a plurality of first holes 51 and at least a portion of the second hole 52 is continuous with the electroconductive paste 40 disposed on the first surface 10A of the insulating resin 10 to serve as the wiring, so that filling into vias and wiring can be achieved using a single member. Accordingly, the wiring board 1 can suppress an increase in the types of members in a double-sided board.

All the first holes 51 can communicate with any of the second holes 52.

The shape of the connection pad portion 22 can be a square shape, an elongated rectangular shape, or a trapezoidal shape or can be a shape including curved portions. It is also possible that the first holes 51 are provided in a portion of the wiring pattern of the metal member 20 without providing the connection pad portion 22.

### Method of Manufacturing Wiring Board

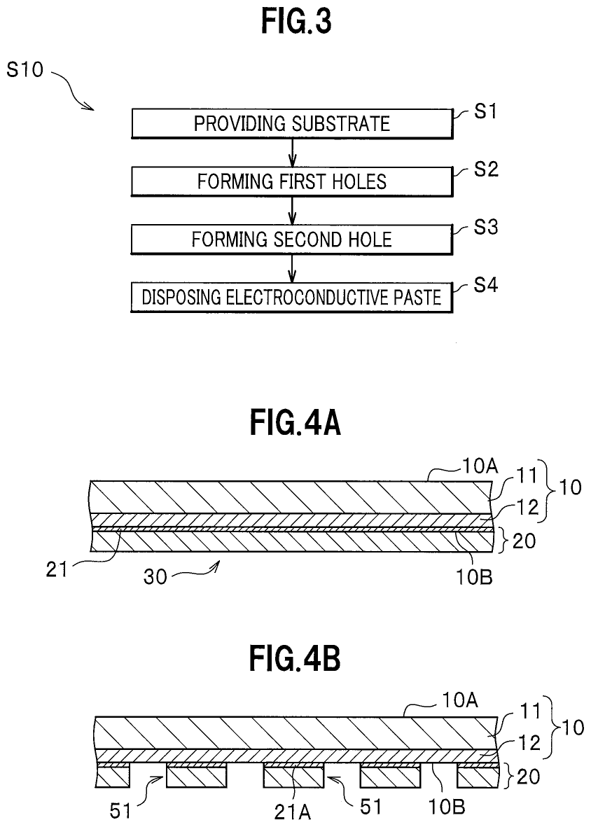

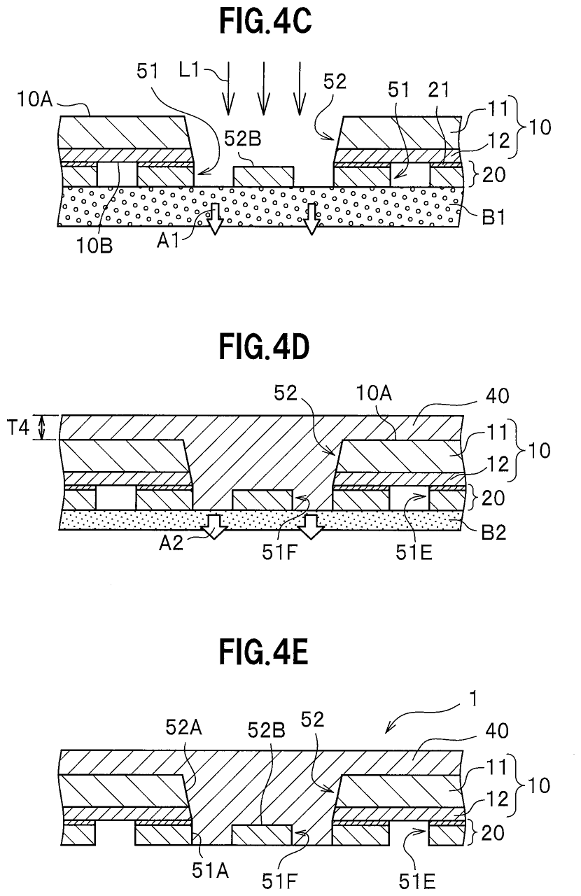

Subsequently, a method S10 of manufacturing the wiring board according to the embodiment will be described referring to FIG. 3 to FIG. 4E. FIG. 3 is a flowchart illustrating the method S10 of manufacturing the wiring board. FIG. 4A to FIG. 4E are schematic cross-sectional views schematically illustrating the method S10 of manufacturing the wiring board.

The method S10 of manufacturing the wiring board includes: a step S1 of providing the substrate 30 including the insulating resin 10 having the first surface 10A and the second surface 10B opposite to the first surface 10A and the metal member 20 provided with the anti-rust layer 21 on the surface facing the second surface 10B of the insulating resin 10; a step S2 of forming a plurality of first holes 51 passing through the metal member 20 by etching in the metal member 20; a step S3 of forming the second hole 52 passing through the insulating resin 10 and communicating with at least one of the first holes 51 from the first surface 10A side of the insulating resin 10; and a step S4 of filling the electroconductive paste 40 to connect the second hole 52 with any of the plurality of first holes 51 and disposing the electroconductive paste 40 on the first surface 10A of the insulating resin 10 to form wiring continuous with the filled electroconductive paste 40, the anti-rust layer 21 on the surface of the metal member 20 being removed from the inner bottom surface 52B of the second hole 52 along with formation of the second hole 52 in the step S3 of forming the second hole 52.

### Providing Substrate

The step S1 of providing a substrate includes providing the substrate 30 in which the metal member 20 is disposed to face one surface (second surface 10B) of the insulating resin 10. In an example, the metal member 20 is copper foil, and copper foil on which the anti-rust layer 21 is formed on the surface on the insulating resin 10 side is used. The metal member 20 is bonded to the polyimide layer 11 serving as the base member of the insulating resin 10 with the resin layer 12 serving as an adhesive layer therebetween. The metal member 20 and the insulating resin 10 bonded together to form a sheet are provided. The material, structure, and thickness of the insulating resin 10 are not particularly limited. For example, the metal member 20 and the polyimide layer 11 can be bonded together by thermocompression bonding or the like without the resin layer 12. This substrate 30 can be provided by purchasing. Alternatively, a material formed by integrally forming the insulating resin 10 using the polyimide layer 11 and the resin layer 12 formed of a polyimide resin can be used.

### Forming First Holes

The step S2 of forming first holes includes forming a plurality of first holes 51 passing through the metal member 20 by etching in the metal member 20. In this step S2, the wiring having the predetermined wiring pattern and the connection pad portion 22 are also formed by etching together with the first holes 51. The number of the first holes 51 is a preset number in the metal member 20. For example, 49 first holes 51 are formed in an array of 7 rows and 7 columns. The first holes 51 are provided in the metal member 20 at positions facing the second holes 52 and around the positions facing the second holes 52 described below. That is, the first holes 51 can be formed at positions not communicating with the second holes 52 in the region facing the second holes 52.

As shown in FIGS. 2A and 2B, the connection pad portion 22 can be formed of the metal member 20, and a plurality of first holes 51 can be formed in the connection pad portion 22. The connection pad portion 22 is only required to be formed to face at least one second hole 52 in a plan view.

The electroconductive paste 40 described below is filled into at least one of a plurality of first holes 51. Accordingly, if a maximum diameter D1 of the first holes 51 is small, the filling is difficult in relation to the viscosity and particle shape of a filler of the electroconductive paste 40. If the maximum diameter D1 of the first holes 51 is large, in relation to the size of the second hole 52, the area of contact with the electroconductive paste 40 on the inner bottom surface 52B of the second hole 52 can be small in some cases, and the electrical resistance of the connection between the electroconductive paste 40 and the metal member 20 becomes large. Accordingly, in the step S2 of forming first holes, the maximum diameter D1 of the first holes 51 to be formed is preferably 30 μm or more and 150 μm or less.

In this step S2, a resist film attached to the metal member 20 is exposed and developed so that a resist pattern is formed so as to provide the predetermined wiring pattern. Etching treatment is then performed to form the wiring having the wiring pattern of the metal member 20, the connection pad portion 22, and the first holes 51 of the connection pad portion 22.

### Forming Second Hole

The step S3 of forming a second hole includes forming in the insulating resin 10 the second hole 52 passing through the insulating resin 10 and removing the anti-rust layer 21 on the surface of the metal member 20 on the inner bottom surface 52B of the second hole 52. In this step S3, for example, the second hole 52 can be formed by laser processing or drilling from the first surface 10A side of the insulating resin 10. In this example, the second hole 52 is formed by applying a laser beam L1 to evaporate the insulating resin 10. The laser to be used is preferably a CO₂ laser from the viewpoint of the processing speed, but a green laser, a UV laser, or the like can also be used.

A maximum diameter D2 of the second holes 52 formed in this step S3 is 1.1 times or more, preferably 1.5 times or more, more preferably 1.8 times or more as large as the maximum diameter D1 of the first holes 51. The maximum diameter D2 of the second holes 52 is 10 times or less, preferably 8 times or less, more preferably 5 times or less as large as the maximum diameter D1 of the first holes 51. In terms of dimensions, the maximum diameter D2 of the second holes 52 is preferably larger than the maximum diameter D1 of the first holes 51 and preferably 55 μm or more and 1,500 μm or less.

As shown in FIG. 4C, in the step S3 of forming a second hole, the second hole 52 is preferably formed along with suction of the insulating resin 10 through the first holes 51. In an example, in this step S3, a porous suction sheet B1 is applied over the first holes 51, and the second hole 52 is formed while suction is performed in the direction from the surface of the suction sheet B1 to arrows A1.

In the step S3 of forming a second hole, the anti-rust layer 21 on the surface of the metal member 20 is removed. For example, the anti-rust layer 21A shown near the center in FIG. 4B has been removed from the inner bottom surface 52B shown in FIG. 4C. In this step S3, as an example, the operation is performed while suction is performed through the suction sheet B1 when the anti-rust layer 21 is removed by irradiation of the laser beam L1. Accordingly, in this step S3, fragments of the anti-rust layer 21 removed and residues of the insulating resin 10 do not remain in the second hole 52, and the subsequent step can be smoothly performed.

An inner lateral surface 52A of the second hole 52 is inclined such that the inner diameter of the second hole 52 becomes smaller toward the first hole 51, and the second hole 52 is preferably formed into what is called a tapered shape. By forming the tapered shape, the electroconductive paste 40 described below is filled along the inner lateral surface 52A and is likely to be disposed in close contact with the inner lateral surface 52A. Further, by forming the tapered shape, disconnection between the electroconductive paste 40 located inside the second hole 52 and the wiring of the electroconductive paste 40 disposed on the first surface 10A of the insulating resin 10 is unlikely to occur.

### Disposing Electroconductive Paste

The step S4 of disposing an electroconductive paste includes filling the electroconductive paste 40 into the first holes 51 and the second hole 52 and disposing the electroconductive paste 40 on the first surface 10A of the insulating resin 10 as the wiring.

In this step S4, the electroconductive paste 40 is filled into the second hole 52 by being injected into the second hole 52 from the first surface 10A side of the insulating resin 10. The electroconductive paste 40 is then filled into the first holes 51 communicating with the second hole 52 but is not filled into the first holes 51 not communicating with the second hole 52. In this step S4, electrical connection can be reliably established by filling the electroconductive paste 40 into one or more first holes 51 at positions facing the second hole 52. The electroconductive paste 40 serving as the wiring is disposed on the first surface 10A of the insulating resin 10 continuously with the second hole 52. In this step S4, the wiring constituted of the electroconductive paste 40 disposed on the first surface 10A is, for example, disposed in a direction orthogonal to the direction of the wiring constituted of the metal member 20 disposed on the second surface 10B and is disposed at a position facing the connection pad portion 22. The wiring constituted of the electroconductive paste 40 does not necessarily lie in the direction orthogonal to the direction of the wiring constituted of the metal member 20.

The electroconductive paste 40 used in this step S4 is fluid and can be disposed by applying and then hardening the electroconductive paste 40. In this step S4, the application of the electroconductive paste 40 can be performed by, for example, injection from a nozzle of a dispenser, screen printing or metal mask printing, or a combination of injection from a nozzle and screen printing, such as screen printing after injection from a nozzle. In this step S4, in any case, application of the electroconductive paste 40 is preferably performed while suction is performed through the first holes 51 communicating with the second hole 52 as shown in FIG. 4D.

In this step S4, instead of the suction sheet B1 in the step S3 of forming the second hole, a sheet of paper B2 is applied over the first holes 51, and the electroconductive paste 40 is applied while suction is performed from the surface of the sheet of paper B2 to the direction of arrows A2. In this step S4, the electroconductive paste 40 is injected into the second hole 52 and the first holes 51 along with suction, so that the electroconductive paste 40 can be reliably filled from the second hole 52 to the first holes 51 continuously. The electroconductive paste 40 filled into the first holes 51 and the second hole 52 is disposed on the inner lateral surface 52A and the inner bottom surface 52B of the second hole 52 and inner lateral surfaces 51A of the first holes 51. For example, the thickness of the sheet of paper B2 used in this step S4 is 20 μm or more and 60 μm or less. The electroconductive paste 40 filled in this step S4 can be hardened, for example, by heat treatment.

After the step S4 of disposing, an electroconductive paste is completed, the sheet of paper B2 is removed, so that the wiring board 1 is formed by the method S10 of manufacturing the wiring board. In the case in which a solder-based material is used for the electroconductive paste, connection can be established by heat treatment with a reflow oven or the like.

In the method S10 of manufacturing the wiring board including the configuration as described above, the position where the second hole 52 is formed can be made flexible by forming a plurality of first holes 51 passing through the metal member 20 in the metal member 20 facing the second surface 10B of the insulating resin 10 and forming the second hole 52 communicating with at least one of the first holes 51. Accordingly, the method S10 of manufacturing the wiring board can facilitate alignment between the first hole 51 and the second hole 52 communicating with the first hole 51. The electrical connection can be reliably established by causing a plurality of first holes 51 to communicate with the second hole 52.

In the method S10 of manufacturing the wiring board, it is made possible to form the second hole 52 while sucking the insulating resin 10 through the first holes 51 by forming the second hole 52 passing through the insulating resin 10 and communicating with at least one first hole 51 from the first surface 10A side of the insulating resin 10. By forming the second hole 52 while sucking the insulating resin 10 through the first holes 51, resin residues and bubbles remaining in the second hole 52 can be reduced to improve the adhesion between the inner lateral surface 52A and the inner bottom surface 52B of the second hole 52 and the electroconductive paste 40.

In the method S10 of manufacturing the wiring board, the electroconductive paste 40 is filled to connect any of a plurality of first holes 51 and the second hole 52, and the electroconductive paste 40 is disposed on the first surface 10A of the insulating resin 10 so as to be wiring continuous with the filled electroconductive paste 40, so that the electroconductive paste 40 can be collectively disposed on the first surface 10A of the insulating resin 10 and in the second hole 52 by, for example, printing, and wiring and filling into vias can be performed in a simple manner. The electroconductive paste 40 is elastic and is therefore unlikely to break due to bending or warping of the wiring board 1, and reliable wiring can be provided.

In the method S10 of manufacturing the wiring board, the anti-rust layer 21 on the surface of the metal member 20 is removed from the inner bottom surface 52B of the second hole 52 while the second hole 52 is formed, so that an increase in the resistance of the anti-rust layer 21 can be suppressed.

In the method S10 of manufacturing the wiring board, the electroconductive paste 40 filled into the first holes 51 and the second hole 52 is disposed on the inner lateral surface 52A and the inner bottom surface 52B of the second hole 52 and the inner lateral surface 51A of the first hole 51, so that the adhesive strength between the electroconductive paste 40 and the substrate 30 can be enhanced, which produces what is called the anchor effect. Further, the electrical resistance of the connection between the electroconductive paste 40 and the metal member 20 can be reduced.

In the method S10 of manufacturing the wiring board, a plurality of first holes 51 passing through the metal member 20 are formed in the metal member 20 by etching, so that the diameter of the first holes 51 can be reduced, and the first holes 51 can be collectively formed regardless of the number of the first holes 51.

In the method S10 of manufacturing the wiring board, the first holes 51 are formed at positions facing the second holes 52 and around the positions facing the second holes 52, so that the first holes 51 at positions other than the portion provided with the second holes 52 can increase the surface area of the metal member 20 and enhance the heat dissipation performance. The electroconductive paste 40 filled into a plurality of first holes 51 allows for dealing with deformation due to bending or warping of the wiring board 1.

In the method S10 of manufacturing the wiring board, the second hole 52 has a tapered shape in which the inner diameter becomes smaller toward the first holes 51, so that the electroconductive paste 40 is easily filled so as to face the inner lateral surface 52A of the second hole 52, and formation of bubbles can be suppressed.

### Planar Light-Emitting Device

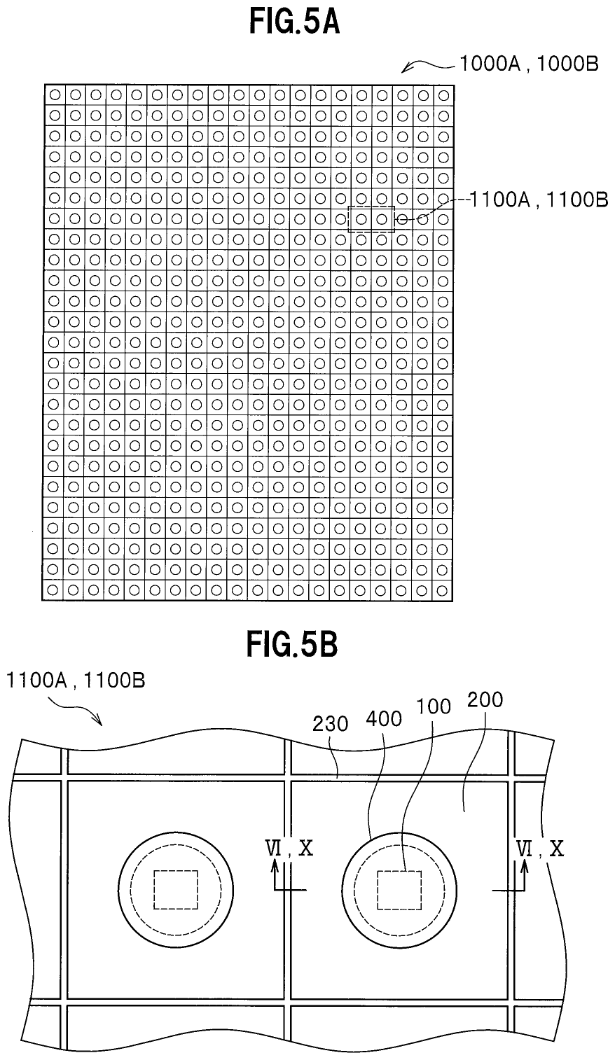

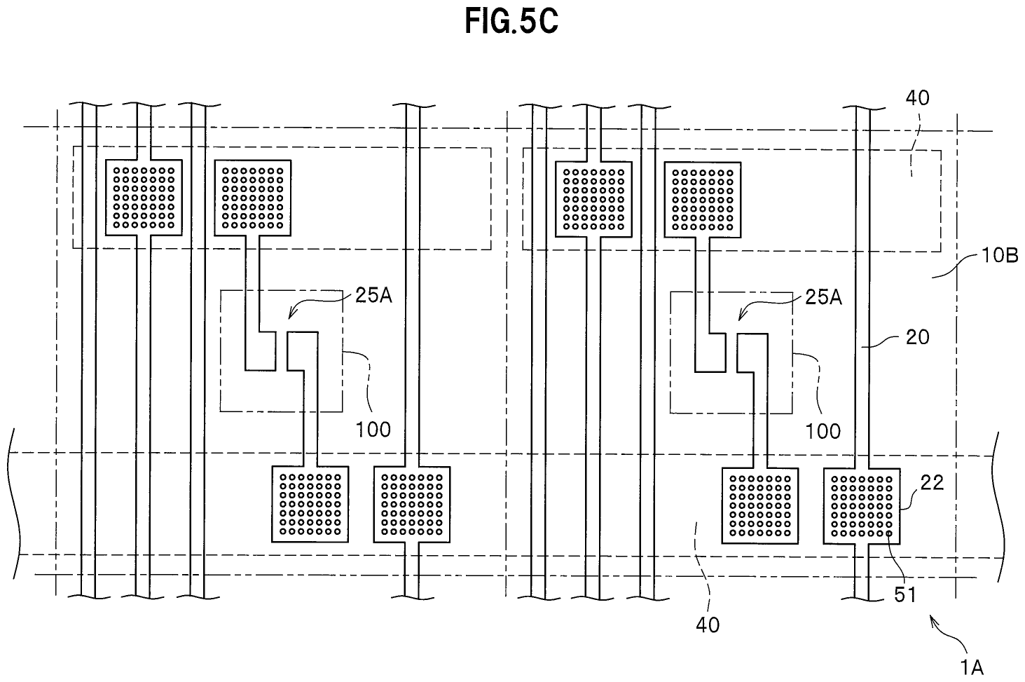

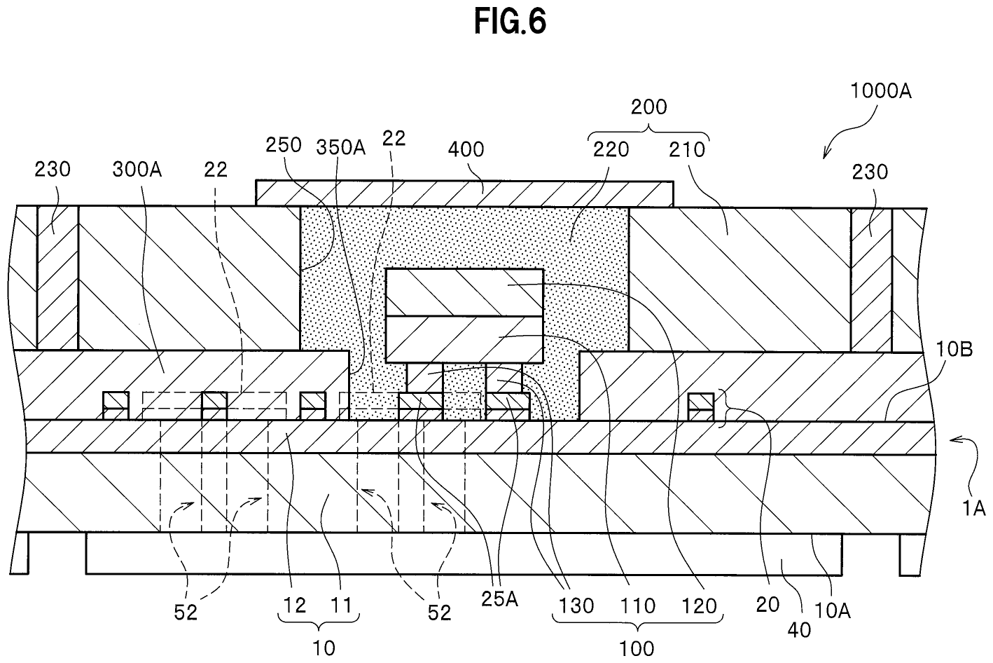

Subsequently, a planar light-emitting device 1000A according to a first embodiment will be described referring to FIG. 5A to FIG. 6. As shown in FIGS. 5A and 5B, the planar light-emitting device 1000A is a device in which light sources 100 are arranged to emit light in a planar manner, and the brightness and turning on and off of each light source 100 can be independently controlled. The planar light-emitting device 1000A is partitioned by a reflective layer 230 described below into sections each including one light source 100, and one light source 100 serves as a cell, which is a unit of control of the brightness and turning on and off. FIG. 5A is a schematic plan view of the overall planar light-emitting device, and FIG. 5B is a schematic enlarged plan view of an example of a portion of the planar light-emitting device shown in FIG. 5A. FIG. 5C is a schematic plan view of an example of the wiring board 1, in which the light sources 100 are disposed on electrodes 25A of the metal member 20. FIG. 6 is a schematic cross-sectional view of an example of a portion of the planar light-emitting device 1000A.

The planar light-emitting device 1000A includes the wiring board 1 described above, the light sources 100 that are disposed on the electrodes 25A of the metal member 20 in the wiring board 1 and include light-emitting elements 110, a light-reflective member 300 covering the metal member 20, and a first light-guiding member 210 covering the light-reflective member 300.

The wiring board 1 having the configuration as described above is used. In the wiring board 1, various patterns of wiring can be formed according to the intended use. The wiring board 1 used for the planar light-emitting device 1000A is a board in which electrodes for arranging the light sources 100 and control wiring are formed for the planar light-emitting device 1000A, and this board will be described as a wiring board 1A.

### Light Source

The light sources 100 each include the light-emitting element 110 including a pair of element electrodes 130 and a light-transmissive member 120 disposed on the light extraction surface side of the light-emitting element 110.

The light-emitting element 110 includes a semiconductor layered body, is provided with the light-transmissive member 120 disposed on the upper surface side of the semiconductor layered body in the present embodiment, and includes the pair of element electrodes 130 on the lower surface side. Any composition can be employed for the semiconductor layered body according to the desired emission wavelength. For example, a nitride semiconductor (InₓAl_{y}Ga_{1-x-y}N, 0≤X, 0≤Y, and X+Y≤1) that can emit blue or green light, GaP, or GaAlAs or AlInGaP that can emit red light can be used. The size and shape of the light-emitting element 110 can be appropriately selected according to the intended purpose.

For example, the light-transmissive member 120 is made of a light-transmissive resin material, such as an epoxy resin, a silicone resin, and a mixture of these resins. The light-transmissive member 120 can contain a phosphor. For example, if a phosphor that absorbs blue light from the light-emitting element 110 and radiates yellow light is contained, the light source 100 can emit white light. The light-transmissive member 120 can contain a plurality of types of phosphors. For example, if a phosphor that absorbs blue light from the light-emitting element 110 and radiates green light and a phosphor that emits red light are contained, the light source 100 can also emit white light.

Examples of such a phosphor include yttrium-aluminum-garnet-based phosphors (such as Y₃(Al,Ga)₅O₁₂:Ce), lutetium-aluminum-garnet-based phosphors (such as Lu₃(Al,Ga)₅O₁₂:Ce), terbium-aluminum-garnet-based phosphors (such as Tb₃(Al,Ga)₅O₁₂:Ce), β-SiAlON phosphors (such as (Si,Al)₃(O,N)₄:Eu), α-SiAlON phosphors (such as Mz(Si,Al)₁₂(O,N)₁₆ (where 0<z≤2, M is Li, Mg, Ca, Y, or a lanthanoid element except for La and Ce)), nitride-based phosphors such as CASN-based phosphors (such as CaAlSiN₃:Eu) and SCASN-based phosphors (such as (Sr,Ca)AlSiN₃:Eu), fluoride phosphors such as KSF-based phosphors (such as K₂SiF₆:Mn), KSAF-based phosphors (such as K₂(Si,Al)F₆:Mn), and MGF-based phosphors (such as 3.5MgO·0.5MgF₂·GeO₂:Mn), and quantum-dot phosphors such as perovskite and chalcopyrite.

### Light-Reflective Member

A light-reflective member 300A is a sheet-like light-reflective member. The light-reflective member 300A is disposed on the second surface 10B of the insulating resin 10 in the wiring board 1A to cover the metal member 20. Here, the light-reflective member 300A has an opening 350A surrounding the light source 100, and the opening 350A surrounds the periphery of the light source 100 at a distance of about 50 μm to 100 μm in a plan view so that the metal member 20 is covered except for a portion located inside the opening 350A. This structure is also employed in a method S100A of manufacturing the planar light-emitting device according to the first embodiment described below.

It is preferable that the light-reflective member 300A have a high reflectance and be white in color to effectively use light emitted from the light source 100. The reflectance of the light-reflective member 300A is, for example, preferably 90% or more, more preferably 94% or more, at the wavelength of light emitted from the light source 100.

A resin sheet (such as a foamed resin sheet) containing a large number of bubbles, a resin sheet containing a light-diffusing material, or the like can be used for the light-reflective member 300A. Examples of the resin used for the light-reflective member 300A include thermoplastic resins such as acrylic resins, polycarbonate resins, cyclic polyolefin resins, poly(ethylene terephthalate) resins, poly(ethylene naphthalate) resins, and polyester resins and thermosetting resins such as epoxy resins and silicone resins. As the light-diffusing material, a known material such as titanium oxide, silica, alumina, zinc oxide, and glass can be used.

### Light-Guiding Member

Alight-guiding member 200 includes the first light-guiding member 210 covering the light-reflective member 300A and a second light-guiding member 220 covering the light source 100. The first light-guiding member 210 is a plate-like or sheet-like light-transmissive member. Here, the first light-guiding member 210 has an opening 250 surrounding the light source 100. The opening 250 surrounds the periphery of the light source 100 at a distance of about 100 μm to 200 μm in a plan view, is located at a position facing the opening 350A of the light-reflective member 300A, and has a size enough to contain the opening 350A. The first light-guiding member 210 therefore covers the light-reflective member 300A except for a portion located inside the opening 250. This structure is also employed in the method S100A of manufacturing the planar light-emitting device according to the first embodiment and first to third modified examples of the first light-guiding member described below. The second light-guiding member 220 is filled into the opening 250 of the first light-guiding member 210 and covers a region from the opening 350A to the light source 100.

Examples of the material of the first light-guiding member 210 include thermoplastic resins such as acrylic, polycarbonates, cyclic polyolefins, poly(ethylene terephthalate), and polyesters and light-transmissive materials such as glass. It is particularly preferable to use a polycarbonate, which is highly transparent and inexpensive. The material of the second light-guiding member 220 is not limited as long as the material is a transparent resin, and a thermosetting resin such as epoxy resins, silicone resins, and acrylic resins is preferably used.

The light-guiding member 200 is partitioned by the reflective layer 230 into cells. The reflective layer 230 is provided for reducing light transmitted from an adjacent cell through the light-guiding member 200. The reflective layer 230 can be formed by incorporating a light-diffusing material into a resin serving as a material of the light-guiding member 200. Examples of the light-diffusing material include titanium oxide, silica, and alumina.

### Light Adjusting Member

The planar light-emitting device 1000A can include a light adjusting member 400. The light adjusting member 400 is a film-like or plate-like member that reflects a portion of light from the light source 100 side toward the light-reflective member 300A side. The light adjusting member 400 is disposed at a position on the surface of the light-guiding member 200 overlapping the light source 100 in a plan view.

The transmittance of the light adjusting member 400 is, for example, preferably 20% or more and 60% or less, more preferably 30% or more and 40% or less, for light from the light source 100. For the material of the light adjusting member 400, for example, a resin material containing a light-diffusing material can be used, or a metal material can be used. For example, the resin material can be a silicone resin, an epoxy resin, or a mixture of these resins. The light-diffusing material can be a known material such as titanium oxide, silica, alumina, zinc oxide, and glass. It is sufficient that the light adjusting member 400 is large enough to include the light source 100 in a plan view at a position facing the light source 100. The light adjusting member 400 has a circular shape in FIG. 5B but can have a rectangular shape or the like.

In the planar light-emitting device 1000A having the constitution as described above, absorption of light by the metal member 20 can be reduced by disposing the light source 100 including the light-emitting element 110 on the electrodes 25A of the metal member 20 in the wiring board 1A and providing the light-reflective member 300A covering the metal member 20, and light from the light source 100 can be efficiently extracted by providing the first light-guiding member 210 covering the light-reflective member 300A.

In the planar light-emitting device 1000A, one light source 100 is regarded as one cell serving as the unit of control of the brightness and turning on and off, but the number of light sources 100 included in one cell can be one or more. For example, four light sources 100 arranged in two rows and two columns or nine light sources 100 arranged in three rows and three columns can serve as one cell.

### Method of Manufacturing Planar Light-Emitting Device

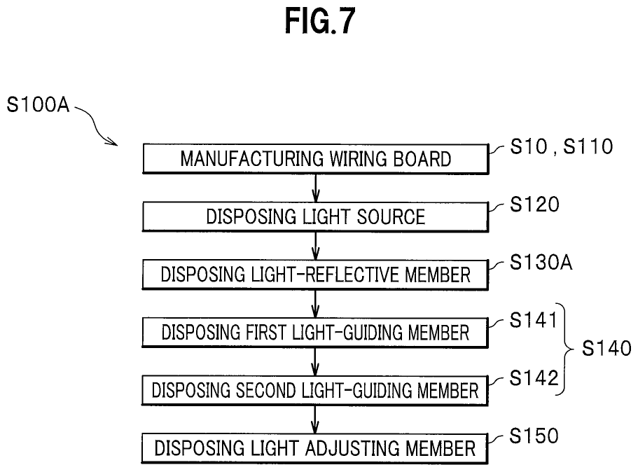

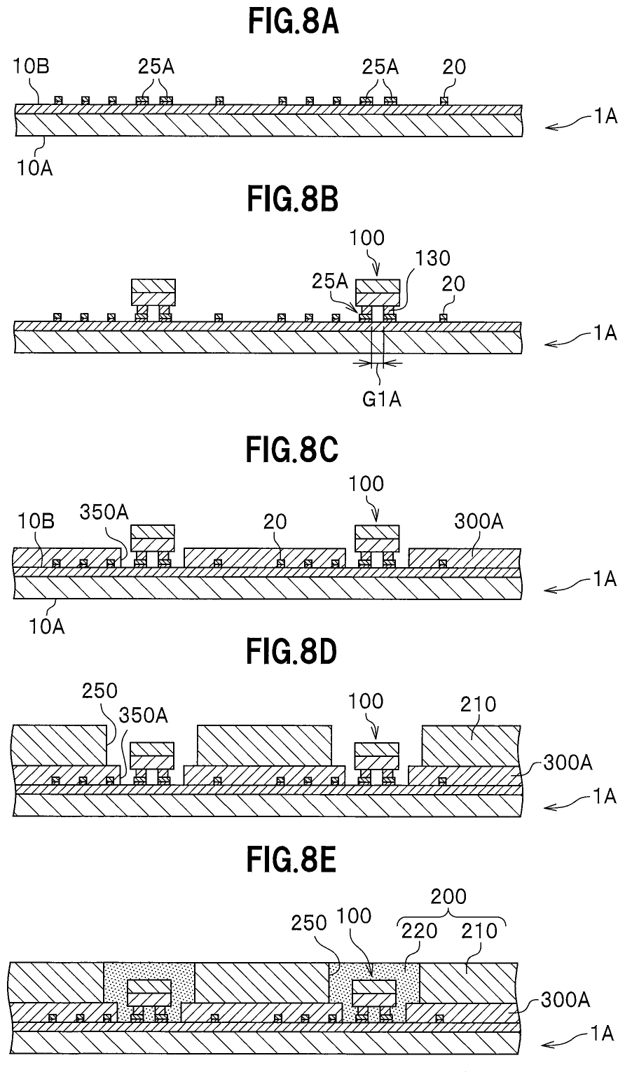

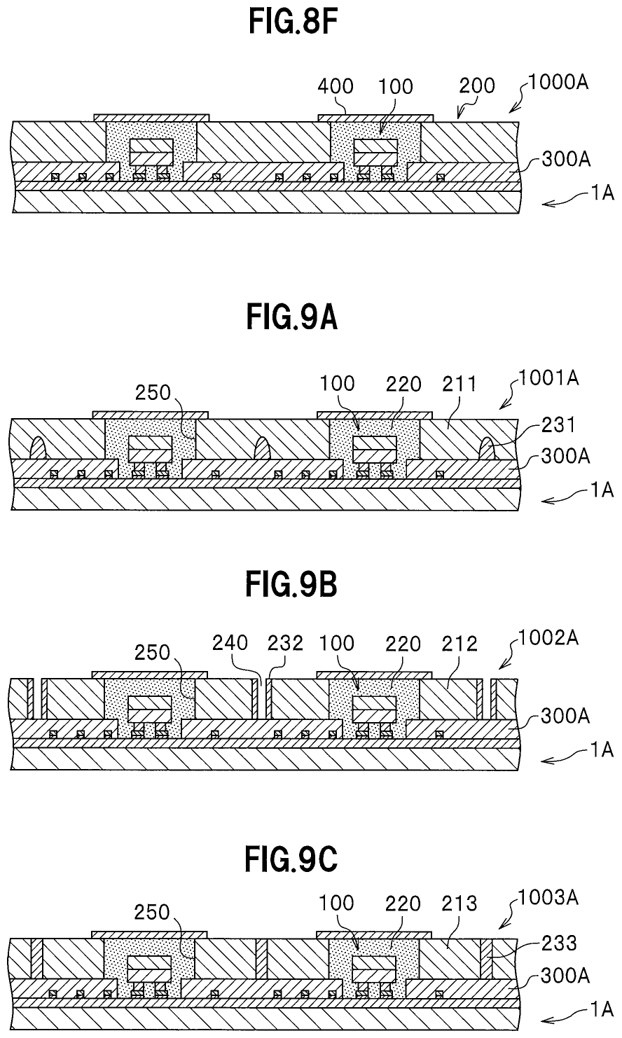

Subsequently, the method S100A of manufacturing the planar light-emitting device according to the first embodiment will be described referring to FIG. 7 to FIG. 8F. FIG. 7 is a flowchart of the method S100A of manufacturing the planar light-emitting device. FIG. 8A to FIG. 8F are schematic cross-sectional views schematically illustrating the method S100A of manufacturing the planar light-emitting device.

The method S100A of manufacturing the planar light-emitting device includes a step S110 of manufacturing the wiring board 1A by the method S10 of manufacturing the wiring board, a step S120 of disposing the light source 100 including the light-emitting element 110 on the electrodes 25A of the metal member 20 in the wiring board 1A, a step S130A of disposing the light-reflective member 300A to cover the metal member 20, and a step S141 of disposing the first light-guiding member 210 to cover the light-reflective member 300A. A step S142 of disposing the second light-guiding member 220 and a step S150 of disposing the light adjusting member 400 can be further included.

### Manufacturing Wiring Board

The step S110 of manufacturing a wiring board includes manufacturing the wiring board 1A by the method S10 of manufacturing the wiring board. In FIG. 8A, the second surface 10B side of the insulating resin 10 on which the metal member 20 is disposed is the upper surface in the drawing. The interval between the electrodes 25A can be adjusted according to the light source 100. In this example, an interval G1A is set such that the electrodes 25A face the pair of element electrodes 130. The electroconductive paste 40 is disposed on the wiring board 1A but is not shown in the cross sections in FIG. 8A to FIG. 8F.

### Disposing Light Source

The step S120 of disposing a light source includes disposing the light source 100 on the wiring board 1A. In the method S100A of manufacturing the planar light-emitting device, the light source 100 is disposed on the electrodes 25A of the metal member 20 in the wiring board 1A. In this step S120, the pair of element electrodes 130 are bonded to the electrodes 25A with electroconductive adhesive members therebetween. Examples of the electroconductive adhesive members include bumps of gold, silver, or copper, electroconductive paste constituted of a mixture of powder of a metal such as gold, silver, copper, platinum, and aluminum and a resin binder, tin-silver-copper (SAC) solder, and tin-bismuth (SnBi) solder. In this example, the light source 100 is disposed by reflow soldering. The electroconductive adhesive members are disposed between the pair of element electrodes 130 and the electrodes 25A.

### Disposing Light-Reflective Member

The step S130A of disposing a light-reflective member includes disposing the light-reflective member 300A to cover the metal member 20. In this step S130A, the light-reflective member 300A has the opening 350A surrounding the light source 100 and is disposed such that the light source 100 is located in the opening 350A. Adhesive sheets having adhesive surfaces or sticky surfaces on both sides are attached to the upper surface and the lower surface of the light-reflective member 300A. The adhesive sheets are made of urethane, an acrylic resin, or the like and have a thickness of about 10 μm to 75 μm. It is desirable that the reflectance of the adhesive sheets be improved by adding titanium oxide, barium sulfate, or the like. It is also possible to use white bonding sheets as the sheets having adhesiveness or stickiness and to use the sheets in a state of being laminated with or sandwiched between white poly(ethylene terephthalate) sheets to further enhance the reflectance. The light-reflective member 300A can be disposed by applying an adhesive without using the adhesive sheets.

### Disposing First Light-Guiding Member

The step S141 of disposing a first light-guiding member includes disposing the first light-guiding member 210 to cover the light-reflective member 300A. In this step S141, the first light-guiding member 210 is a plate-like or sheet-like member having the opening 250 surrounding the light source 100 and is disposed such that the light source 100 is located in the opening 250. In this step S141, the first light-guiding member 210 is aligned and pressurized in the direction of the wiring board 1A while being heated to be laminated on the light-reflective member 300A. In this step S141, the first light-guiding member 210 includes a reflective layer that has been formed in advance at a predetermined position (see FIG. 6).

### Disposing Second Light-Guiding Member

The method S100A of manufacturing the planar light-emitting device can include the step S142 of disposing a second light-guiding member. The step S142 of disposing a second light-guiding member includes disposing the second light-guiding member 220 to cover the light source 100. In this step S142, the second light-guiding member 220 can be disposed to cover the light source 100 by injecting a resin in the form of liquid or paste through the opening 250 of the first light-guiding member 210 and curing the resin. The material of the second light-guiding member 220 can be the same as or different from the material of the first light-guiding member 210. In this step S142, the same material as the first light-guiding member 210 is injected through the opening 250 in an uncured state and then cured.

A step S140 of disposing a light-guiding member is the combination of the step S141 of disposing a first light-guiding member and the step S142 of disposing a second light-guiding member.

### Disposing Light Adjusting Member

The method S100A of manufacturing the planar light-emitting device can include the step S150 of disposing a light adjusting member. The step S150 of disposing a light adjusting member includes disposing the light adjusting member 400 at a position on the surface of the light-guiding member 200 overlapping the light source 100 in a plan view. In this step S150, the light adjusting member 400 can be provided by applying and curing a resin serving as the material on the light-guiding member 200 or by disposing a film-like or plate-like member. In this step S150, as an example, a silicone resin containing titanium oxide is applied at a position on the surface of the light-guiding member 200 facing the light source 100.

The method S100A of manufacturing the planar light-emitting device having the configuration as described above can further reduce the production time and the number of steps for the planar light-emitting device by reducing the production time and the number of steps for the wiring board by the method S10 of manufacturing the wiring board, disposing the light source 100 on the electrodes 25A of the metal member 20, disposing the light-reflective member 300A to cover the metal member 20, and disposing the first light-guiding member 210 to cover the light-reflective member 300A.

### Modified Examples of Light-Guiding Member

Subsequently, modified examples of the first light-guiding member will be described with reference to FIG. 9A to FIG. 9C.

In a planar light-emitting device 1001A according to the first modified example of the first light-guiding member schematically shown in FIG. 9A, a reflective layer 231 has a semi-elliptic cross-sectional shape. The width of the cross section of the reflective layer 231 is preferably largest at a position facing the light-reflective member 300A and decreases toward the upper surface of a first light-guiding member 211. In this case, the reflective layer 231 is not disposed at a position near the upper surface of the first light-guiding member 211.

The width of the cross section of the reflective layer 231 can be largest at the upper surface of the first light-guiding member 211 and decrease toward the lower surface. In this case, the reflective layer 231 is not disposed at a position near the lower surface of the first light-guiding member 211.

In the first modified example of the first light-guiding member, the reflective layer 231 partitioning the first light-guiding member 211 between adjacent light sources 100 is not disposed at a position near the upper or lower surface of the first light-guiding member 211, so that a portion of light can spread beyond the region partitioned by the reflective layer 231. In the first modified example, the difference between brightness and darkness between adjacent light sources 100 can therefore be made inconspicuous. In the first modified example, the brightness near the reflective layer 231 can be adjusted by adjusting the width of the reflective layer 231 toward the upper or lower surface of the first light-guiding member 211.

In a planar light-emitting device 1002A according to the second modified example of the first light-guiding member schematically shown in FIG. 9B, a reflective layer 232 has a rectangular cross-sectional shape and has a uniform width from the lower surface to the upper surface of a first light-guiding member 212. The reflective layer 232 has a gap 240 between the reflective layer 232 and an adjacent first light-guiding member 212.

The first light-guiding member 212 provided with the reflective layer 232 can be formed by, for example, singulating the first light-guiding member not provided with the reflective layer into sections each including one light source 100 and having the same size and applying the material of the reflective layer to the outer peripheral surface of the singulated first light-guiding member.

In the second modified example of the first light-guiding member, the reflective layer 232 includes two layers between adjacent light sources 100 because the gap 240 is provided between adjacent reflective layers 232, and an air layer can be provided between the two layers. The second modified example can thus more strongly suppress spread of light beyond the region partitioned by the reflective layer 232.

In a planar light-emitting device 1003A according to the third modified example of the first light-guiding member schematically shown in FIG. 9C, a reflective layer 233 has a rectangular cross-sectional shape and has a uniform width from the lower surface to the upper surface of a first light-guiding member 213.

The first light-guiding member 213 provided with the reflective layer 233 can be formed by, for example, singulating the first light-guiding member not provided with the reflective layer into sections each including one light source 100 and having the same size in the same manner as in the second modified example and inserting the singulated first light-guiding members into a grating of the reflective layer 233 that has been formed into the shape of a grating.

In the third modified example of the first light-guiding member, separately forming the first light-guiding member 213 and the reflective layer 233 allows the first light-guiding member 213 and the reflective layer 233 each having a surface to face each other. In the third modified example, the reflectance at the boundary between the first light-guiding member 213 and the reflective layer 233 can thus be enhanced, and suppression of spread of light and improvement in the light extraction efficiency can be achieved.

In the first to third modified examples of the first light-guiding member, the opening 250 surrounding the light source 100 is formed in the same manner as for the first light-guiding member 210. The first to third modified examples can also apply to a planar light-emitting device according to a second embodiment in the same manner.

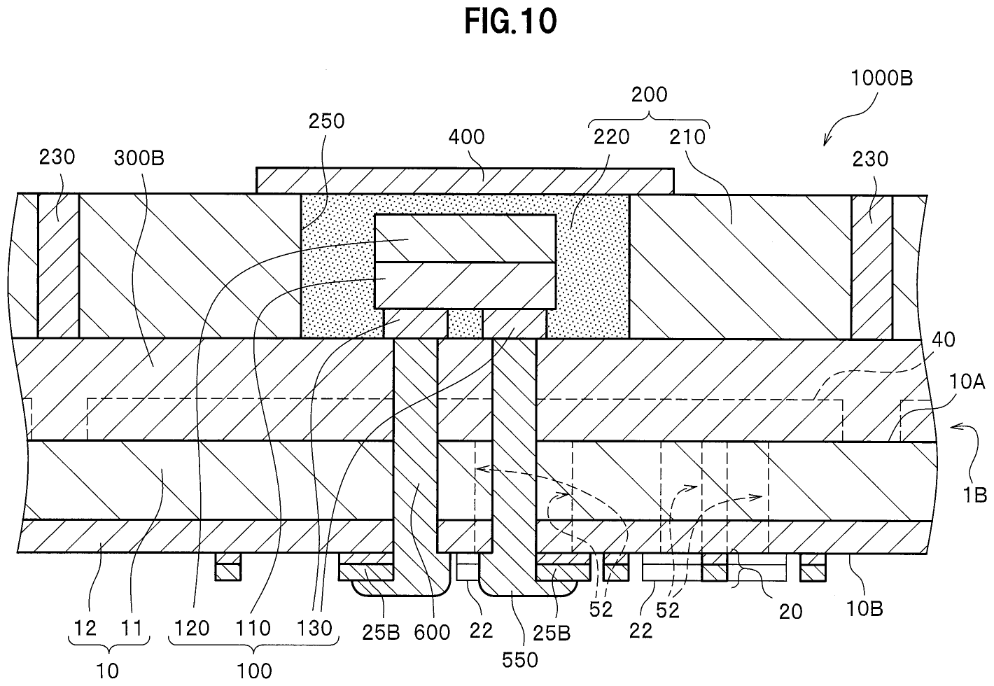

Subsequently, a planar light-emitting device 1000B according to the second embodiment will be described referring to FIG. 10. FIG. 10 is a schematic cross-sectional view of an example of a portion of the planar light-emitting device 1000B. Similarly to the planar light-emitting device 1000A described above, the planar light-emitting device 1000B is a device in which the light sources 100 are arranged on the wiring board 1 to emit light in a planar manner. In the planar light-emitting device 1000B, the first surface 10A and the second surface 10B of the wiring board 1 are inverted.

The planar light-emitting device 1000B includes the wiring board 1, a light-reflective member 300B covering the first surface 10A of the insulating resin 10 in the wiring board 1 and the electroconductive paste 40, the light source 100 that is disposed on the first surface 10A side of the insulating resin 10 and includes the light-emitting element 110, the light-guiding member 200 covering the light source 100 and the light-reflective member 300B, and the light adjusting member 400 disposed at a position on the surface of the light-guiding member 200 overlapping the light source 100 in a plan view.

In this example, the wiring board 1 for the planar light-emitting device 1000B is referred to as a wiring board 1B, and features different from the features of the planar light-emitting device 1000A will be described.

The planar light-emitting device 1000B differs from the planar light-emitting device 1000A in the arrangement of the light source 100 and the light-reflective member 300B and the configuration relating to connection of the light source 100. The interval of electrodes 25B in the wiring board 1B is larger than the interval of the electrodes 25A in the wiring board 1A.

### Arrangement of Light Source and Light-Reflective Member

In the planar light-emitting device 1000B, the light source 100 and the light-reflective member 300B are disposed on the first surface 10A of the insulating resin 10 in the wiring board 1B. The light-reflective member 300B is interposed between the light source 100 and the wiring board 1B. As indicated by broken lines in FIG. 10, the light-reflective member 300B covers the electroconductive paste 40 filled into the second hole 52 and the electroconductive paste 40 disposed on the first surface 10A. The reflectance and material of the light-reflective member 300B are the same as for the light-reflective member 300A.

### Connection of Light Source

The pair of element electrodes 130 of the light source 100 are connected to the metal member 20 of the wiring board 1B via connecting members 600 passing through the light-reflective member 300B and the wiring board 1B. The connecting members 600 each include a region 550 that extends to the surface of the metal member 20 and is connected to the surface of the metal member 20.

The light-guiding member 200 and the light adjusting member 400 are common with the planar light-emitting device 1000A, and the description is omitted.

In the planar light-emitting device 1000B having the constitution as described above, absorption of light by the electroconductive paste 40 can be reduced by disposing the light source 100 including the light-emitting element 110 on the first surface 10A side of the insulating resin 10 in the wiring board 1B and providing the light-reflective member 300B covering the first surface 10A of the insulating resin 10 and the electroconductive paste 40. The light-guiding member 200 covering the light source 100 and the light-reflective member 300B allows light from the light source 100 to be efficiently extracted. The light adjusting member 400 disposed at a position on the surface of the light-guiding member 200 overlapping the light source 100 in a plan view can weaken light directly above the light source 100 on the light extraction surface of the planar light-emitting device 1000B and therefore increase the uniformity of the luminance of the light extraction surface.

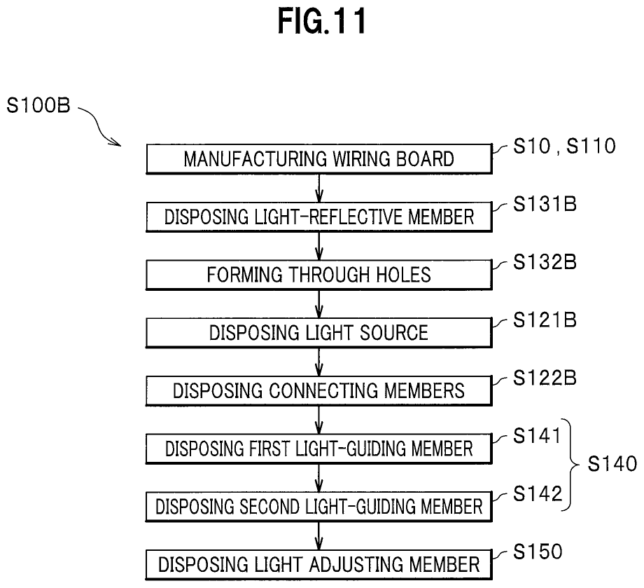

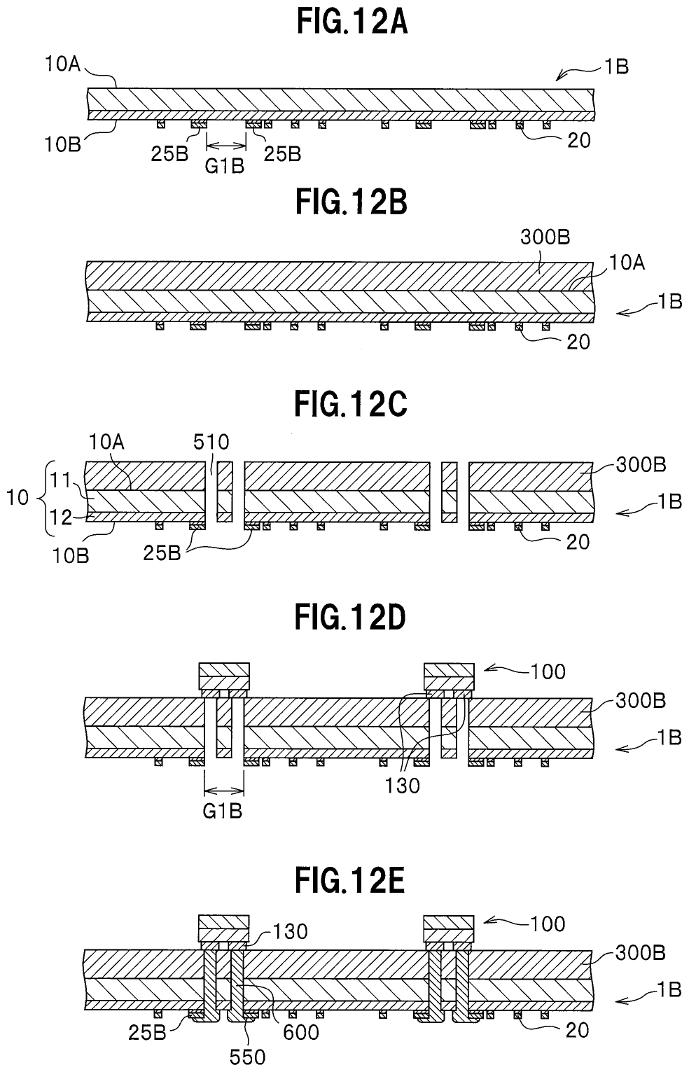

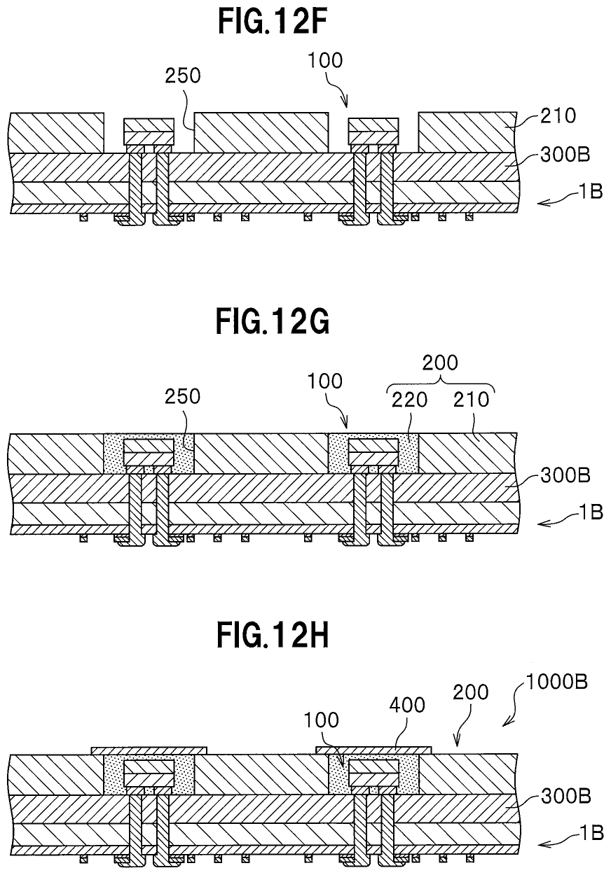

Subsequently, a method S100B of manufacturing the planar light-emitting device according to the second embodiment will be described referring to FIG. 11 to FIG. 12H. FIG. 11 is a flowchart of the method S100B of manufacturing the planar light-emitting device. FIG. 12A to FIG. 12H are schematic cross-sectional views schematically illustrating the method S100B of manufacturing the planar light-emitting device.

The method S100B of manufacturing the planar light-emitting device includes: the step S110 of manufacturing the wiring board 1B by the method S10 of manufacturing a wiring board; a step S131B of disposing the light-reflective member 300B to cover the first surface 10A of the insulating resin 10 in the wiring board 1B and the electroconductive paste 40; a step S121B of disposing the light source 100 including the light-emitting element 110 on the first surface 10A side of the insulating resin 10; the step S140 of disposing the light-guiding member 200 to cover the light source 100 and the light-reflective member 300B; and the step S150 of disposing the light adjusting member 400 at a position on the surface of the light-guiding member 200, the position overlapping the light source 100 in a plan view. The method S100B of manufacturing the planar light-emitting device in this example also includes a step S132B of forming through holes 510 and a step S122B of disposing the connecting members 600. Description of the step S140 of disposing the light-guiding member 200 and the step S150 of disposing the light adjusting member 400 is omitted not to repeat the description given for the method S100A of manufacturing the planar light-emitting device.

### Manufacturing Wiring Board

The step S110 of manufacturing a wiring board includes manufacturing the wiring board 1B by the method S10 of manufacturing the wiring board. In FIG. 12A, the first surface 10A side of the insulating resin 10 is the upper surface in the drawing. In this example, the interval between the electrodes 25B is an interval G1B larger than in the wiring board 1A. The electroconductive paste 40 is disposed on the wiring board 1B but is not shown in the cross-sectional views of FIG. 12A to FIG. 12H.

### Disposing Light-Reflective Member

The step S131B of disposing a light-reflective member includes disposing the light-reflective member 300B to cover the first surface 10A of the insulating resin 10 and the electroconductive paste 40. In this step S131B, the opening surrounding the light source 100 is not formed in the light-reflective member 300B. In this step S131B, the light-reflective member 300B can be disposed to cover the entire surface of the wiring board 1B. In this step S131B, at a position not shown in FIG. 12B to FIG. 12G, the light-reflective member 300B covers the electroconductive paste 40 filled into the second hole 52 and the electroconductive paste 40 disposed on the first surface 10A.

Adhesive sheets are attached to the upper surface and the lower surface of the light-reflective member 300B in the same manner as for the light-reflective member 300A. The upper surface of the light-reflective member 300B in the drawings has stickiness. With this stickiness, in the step S121B of disposing a light source described below, the pair of element electrodes 130 can be held, and the light source 100 can be fixed. The light-reflective member 300B can be disposed by applying an adhesive without using the adhesive sheets. After lamination, the light-reflective member 300B is pressurized in the direction of the wiring board 1B while being heated. The surface of the light-reflective member 300B on the upper surface side not facing the wiring board 1B is thus in a fluid state, which facilitates the process of making holes and arrangement of the light source in subsequent steps.

### Forming Through Holes

The step S132B of forming through holes includes forming the through holes 510 passing through the light-reflective member 300B and the wiring board 1B. In this step S132B, the through holes 510 are formed at positions intended to face the pair of element electrodes 130 of the light source 100 disposed in the subsequent step to pass through the light-reflective member 300B and the insulating resin 10. The electrodes 25B are located in contact with the openings of the through holes 510 on the second surface 10B side of the insulating resin 10.

In the step S132B of forming through holes, the through holes 510 may be formed from the light-reflective member 300B side or from the second surface 10B side of the insulating resin 10. The through holes 510 can be formed by laser processing or drilling.

### Disposing Light Source

The step S121B of disposing a light source includes disposing the light source 100 on the light-reflective member 300B. In this step S121B, the light source 100 is disposed such that the pair of element electrodes 130 face the through holes 510. In this step S121B, for example, the interval G1B can be an interval spaced by two through holes 510. As described above, the upper surface of the light-reflective member 300B in the drawings has stickiness and can hold the light source 100 until the connection by the connecting members 600 is established in the step S122B of disposing connecting members.

### Disposing Connecting Members

The step S122B of disposing connecting members includes filling the connecting members 600 into the through holes 510 and disposing the connecting members 600 on the surfaces of the electrodes 25B. In this step S122B, the connecting members 600 are filled into the through holes 510 to connect the pair of element electrodes 130 to the electrodes 25B.

In the step S122B of disposing connecting members, the connecting members 600 are filled into the through holes 510 and then disposed to extend on the surfaces of the electrodes 25B. In the step S122B of disposing connecting members, the connecting members 600 each include the region 550 connected to the surface of the electrode 25B, so that the electrical connection can be made reliable. For the material of the connecting member 600, the same material as the material of the electroconductive paste 40 or solder can be used.

In the method S100B of manufacturing the planar light-emitting device having the constitution as described above, the production time and the number of steps for the wiring board can be reduced by the method S10 of manufacturing the wiring board. By disposing the light-reflective member 300B to cover the first surface 10A of the insulating resin 10 and the electroconductive paste 40 and disposing the light source 100 on the first surface 10A side of the insulating resin 10, the light-reflective member 300B can be disposed more closely to the light source 100, and the light extraction efficiency can be improved.

In the method S100B of manufacturing the planar light-emitting device, by disposing the light-guiding member 200 to cover the light source 100 and the light-reflective member 300B and disposing the light adjusting member 400 at a position on the surface of the light-guiding member 200 overlapping the light source 100 in a plan view, the production time and the number of steps for the planar light-emitting device can be further reduced while suppressing increase in members.

1. A method of manufacturing a wiring board, the method comprising:
providing a substrate including an insulating resin having a first surface and a second surface opposite to the first surface and a metal member provided with an anti-rust layer on a surface facing the second surface of the insulating resin;
forming a plurality of first holes passing through the metal member by etching in the metal member;
forming a second hole passing through the insulating resin and communicating with at least one of the first holes from a first surface side of the insulating resin; and
filling an electroconductive paste to connect the second hole with at least one first hole of the plurality of first holes and disposing the electroconductive paste on the first surface of the insulating resin to form wiring continuous with the filled electroconductive paste,
wherein, in the forming of the second hole, the anti-rust layer on the surface of the metal member is removed from an inner bottom surface of the second hole along with formation of the second hole.

2. The method of manufacturing a wiring board according to claim 1, wherein the electroconductive paste filled into the second hole and the at least one first hole is disposed on an inner lateral surface and the inner bottom surface of the second hole and an inner lateral surface of the at least one first hole.

3. The method of manufacturing a wiring board according to claim 1, wherein the plurality of first holes are provided in the metal member at positions facing and around the positions facing the second hole.

4. The method of manufacturing a wiring board according to claim 1, wherein the second hole is formed while the insulating resin is sucked through the plurality of first holes in the forming of the second hole.

5. The method of manufacturing a wiring board according to claim 1, wherein a maximum diameter of the plurality of first holes is 30 μm or more and 150 μm or less.

6. The method of manufacturing a wiring board according to claim 1, wherein a maximum diameter of the second hole is 1.1 times or more as large as a maximum diameter of the plurality of first holes.

7. The method of manufacturing a wiring board according to claim 6, wherein the maximum diameter of the second hole is larger than the maximum diameter of the plurality of first holes and is 55 μm or more and 1,500 μm or less.

8. A method of manufacturing a planar light-emitting device, the method comprising:
manufacturing the wiring board by the method of manufacturing a wiring board according to claim 1;
disposing a light source including a light-emitting element on the metal member of the wiring board;
disposing a light-reflective member to cover the metal member; and
disposing a first light-guiding member to cover the light-reflective member.

9. A method of manufacturing a planar light-emitting device, the method comprising:
manufacturing the wiring board by the method of manufacturing a wiring board according to claim 1;
disposing a light-reflective member to cover the first surface of the insulating resin in the wiring board and the electroconductive paste;
disposing a light source including a light-emitting element on the first surface side of the insulating resin;
disposing a light-guiding member to cover the light source and the light-reflective member; and
disposing a light adjusting member at a position on a surface of the light-guiding member, the position overlapping the light source in a plan view.

10. A wiring board comprising:
a substrate including an insulating resin having a first surface and a second surface opposite to the first surface and a metal member provided with an anti-rust layer on a surface facing the second surface of the insulating resin; and
an electroconductive paste disposed on the substrate,
wherein a plurality of first holes pass through the metal member,
wherein a second hole passes through the insulating resin and communicates with at least one first hole of the plurality of first holes,
wherein the anti-rust layer on the surface of the metal member is absent from an inner bottom surface of the second hole, and
wherein the electroconductive paste is filled to connect at least a portion of the second hole with the at least one first hole of the plurality of first holes and disposed on the first surface of the insulating resin to form wiring continuous with the filled electroconductive paste.

11. The wiring board according to claim 10,
wherein the plurality of first holes are provided in the metal member at positions facing and around the positions facing the second hole, and
wherein the electroconductive paste is not filled into the first hole around the positions facing the second hole.

12. The wiring board according to claim 10,
wherein the metal member includes a connection pad portion facing the second hole in a plan view, and
wherein the plurality of first holes are provided in the connection pad portion.

13. A planar light-emitting device comprising:
the wiring board according to claim 10;
a light source including a light-emitting element, the light source disposed on the metal member of the wiring board;
a light-reflective member covering the metal member; and
a first light-guiding member covering the light-reflective member.

14. A planar light-emitting device comprising:
the wiring board according to claim 10;
a light-reflective member covering the first surface of the insulating resin in the wiring board and the electroconductive paste;
a light source including a light-emitting element, the light source disposed on a first surface side of the insulating resin;
a light-guiding member covering the light source and the light-reflective member; and
a light adjusting member disposed at a position on a surface of the light-guiding member, the position overlapping the light source in a plan view.

15. The method of manufacturing a wiring board according to claim 2, wherein the plurality of first holes are provided in the metal member at positions facing and around the positions facing the second hole.

16. The method of manufacturing a wiring board according to claim 2, wherein the second hole is formed while the insulating resin is sucked through the plurality of first holes in the forming of the second hole.

17. The method of manufacturing a wiring board according to claim 2, wherein a maximum diameter of the plurality of first holes is 30 μm or more and 150 μm or less.

18. The wiring board according to claim 11,
wherein the metal member includes a connection pad portion facing the second hole in a plan view, and
wherein the plurality of first holes are provided in the connection pad portion.

19. A planar light-emitting device comprising:
the wiring board according to claim 11;
a light source including a light-emitting element, the light source disposed on the metal member of the wiring board;
a light-reflective member covering the metal member; and
a first light-guiding member covering the light-reflective member.

20. A planar light-emitting device comprising:
the wiring board according to claim 11;
a light-reflective member covering the first surface of the insulating resin in the wiring board and the electroconductive paste;
a light source including a light-emitting element, the light source disposed on a first surface side of the insulating resin;
a light-guiding member covering the light source and the light-reflective member; and
a light adjusting member disposed at a position on a surface of the light-guiding member, the position overlapping the light source in a plan view.
